(19) United States
(12) Patent Application Publication
(10) Pub. No.: US 2018/0114829 A1
(43) Pub. Date: Apr. 26, 2018

(54) Semiconductor Device

(71) Applicant: TOYOTA JIDOSHA KABUSHIKI KAISHA, Toyota-shi (JP)

(72) Inventors: Tatsuji NAGAOKA, Nagakute-shi (JP); Yukihiko WATANABE, Nagakute-shi (JP); Yasushi URAKAMI, Kariya-shi (JP)

(73) Assignee: TOYOTA JIDOSHA KABUSHIKI KAISHA, Toyota-shi (JP)

(21) Appl. No.: 15/700,919

(22) Filed: Sep. 11, 2017

(30) Foreign Application Priority Data
Oct. 20, 2016 (JP) 2016-205823

(51) Int. Cl. H01L 29/06; H01L 29/78

(52) U.S. Cl. CPC H01L 29/063; H01L 29/7813; H01L 29/7804

(57) ABSTRACT

A semiconductor device includes a semiconductor substrate configured such that a trench is provided on a surface of the semiconductor substrate at a position of at least one of a boundary region disposed between a field-effect transistor region and a diode region, a boundary region disposed between the diode region and a peripheral voltage withstanding region, and a boundary region disposed between the field-effect transistor region and the peripheral voltage withstanding region; an insulating film covering an inner surface of the trench; and an electrode film covering an inner surface of the insulating film, the electrode film being configured to be electrically connected to one of a source electrode and an anode electrode.

### INCORPORATION BY REFERENCE

The disclosure of Japanese Patent Application No. 2016-205823 filed on Oct. 20, 2016 including the specification, drawings and abstract is incorporated herein by reference in its entirety.

### BACKGROUND

### 1. Technical Field

The present specification discloses a semiconductor device.

### 2. Description of Related Art

As described in Japanese Patent Application Publication No. 2002-373989 (JP 2002-373989 A), a combination of various regions, e.g., a combination of an FET region, a diode region, and a peripheral voltage withstanding region, a combination of an FET region and a diode region, a combination of a diode region and a peripheral voltage withstanding region, or a combination of an FET region and a peripheral voltage withstanding region, may be formed in one semiconductor substrate. That is, there is a semiconductor device including a boundary region disposed between an FET region and a diode region, a boundary region disposed between a diode region and a peripheral voltage withstanding region, or a boundary region disposed between an FET region and a peripheral voltage withstanding region.

A p-type region serving as a body region is formed in the FET region. In a case where trench gate electrodes are used, a p-type region may be formed to surround a formation area in which the group of the trench gate electrodes is formed. An electric field concentration easily occurs around a p-type region extending from the FET region to the “boundary region disposed between the FET region and the diode region” or from the FET region to the “boundary region disposed between the FET region and the peripheral voltage withstanding region.”

In the peripheral voltage withstanding region, a p-type region serving as a guard ring or a Reduced Surface Field (RESURF) layer is formed. An electric field concentration easily occurs around the p-type region extending from the peripheral voltage withstanding region to the “boundary region disposed between the peripheral voltage withstanding region and the FET region” or from the peripheral voltage withstanding region to the “boundary region disposed between the peripheral voltage withstanding region and the diode region.”

Some diodes use a p-type region, such as a Junction Barrier Schottky Diode (JBS diode) or a Merged PIN Schottky Diode (MPS diode). In the case of the diode using a p-type region, an electric field concentration easily occurs around a p-type region extending from the diode region to the “boundary region disposed between the diode region and the FET region” or from the diode region to the “boundary region disposed between the diode region and the peripheral voltage withstanding region.”

### SUMMARY

The present specification discloses a technique that reduces an electric field concentration that easily occurs around a p-type region extending into a boundary region from a region (that is, an FET region, a diode region, or a peripheral voltage withstanding region) adjacent to the boundary region.

A semiconductor device described in the present specification includes at least one of a boundary region disposed between a field-effect transistor region and a diode region, a boundary region disposed between the diode region and a peripheral voltage withstanding region, and a boundary region disposed between the field-effect transistor region and the peripheral voltage withstanding region, and a trench is provided on a surface of a semiconductor substrate at a position of the at least one boundary region. An inner surface of the trench is covered with an insulating film, and an inner surface (a surface facing an inner side of the trench) of the insulating film is covered with an electrode film. The electrode film is configured to be electrically connected to a source electrode of the field-effect transistor (FET) or an anode electrode of the diode.

When the trench, the insulating film, and the electrode film are provided in the boundary region, an electric field concentration that easily occurs in the boundary region occurs in an inside of the insulating film, thereby making it possible to prevent occurrence of the electric field concentration in the semiconductor in the boundary region. This improves a withstand voltage of the semiconductor device. It is possible to deal with the electric field concentration occurring in the insulating film by selecting a thickness and a material of the insulating film. Thus, a required withstand voltage is easily secured.

In a case where the field-effect transistor region is adjacent to the boundary region, the field-effect transistor region includes a p-type region serving as a body region or a p-type region surrounding a formation area in which a group of trench gate electrodes is provided. In a case where the peripheral voltage withstanding region is adjacent to the boundary region, the peripheral voltage withstanding region includes a p-type region constituting a guard ring or a reduced surface field (RESURF) structure. In a case where a JBS diode or a MPS diode is adjacent to the boundary region, the diode region includes a p-type region. In a case where a p-type region is provided in an adjacent region, a bottom surface of the electrode film (the electrode film provided in the trench) may be disposed at a position deeper than a bottom surface of the p-type region. Thus, an electric field concentration that easily occurs in the related art is suppressed effectively.

Further, the p-type region provided in the adjacent region may reach a side surface of the trench.

In a case where the field-effect transistor region is adjacent to the boundary region and a trench gate electrode is provided in the field-effect transistor region, a bottom surface of the electrode film may be disposed at a position deeper than a bottom surface of the trench gate electrode.

In order to improve the withstand voltage of the semiconductor device or in order to suppress a decrease of the withstand voltage, an n-type impurity low concentration region having an impurity concentration lower than that of an n-type drift layer may be provided in the boundary region. In this case, the trench may be provided in the n-type impurity low concentration region.

The insulating film covering the inner surface of the trench may be thicker than a gate insulating film insulating a gate electrode from the semiconductor substrate. It is possible to maintain a large potential difference with the use of an insulating film, and to prevent occurrence of a large electric field concentration in the semiconductor.

The insulating film covering a bottom surface of the trench may be thicker than the insulating film covering a side surface of the trench. In a part where an electric field concentration easily occurs, the insulating film may be made thick.

A relative permittivity of the insulating film may be higher than a relative permittivity of the semiconductor substrate. This increases an effect of reducing the electric field concentration in the semiconductor with the use of the insulating film.

### BRIEF DESCRIPTION OF THE DRAWINGS

Features, advantages, and technical and industrial significance of exemplary embodiments of the disclosure will be described below with reference to the accompanying drawings, in which like numerals denote like elements, and wherein:

FIG. 1 is a longitudinal section of a semiconductor device according to a first embodiment;

FIG. 2 is a longitudinal section of a semiconductor device according to a second embodiment;

FIG. 3 is a plan view of a semiconductor device according to a third embodiment;

FIG. 4 is a sectional view taken along a line IV-IV in FIG. 3; and

FIG. 5 is a sectional view taken along a line V-V in FIG. 3.

### DETAILED DESCRIPTION OF EMBODIMENTS

Features of embodiments will be described below. Feature 1 is as follows. A trench is formed in a boundary region disposed between a field-effect transistor (FET) region and a diode region including a p-type region. A p-type body region (or a p-type region surrounding a group of trench gate electrodes) of the FET and the p-type region of the diode are in contact with the trench. Feature 2 is as follows. A trench is formed in each boundary region disposed between an FET region and a peripheral voltage withstanding region. Each of a p-type body region (or a p-type region surrounding a group of trench gate electrodes) of the FET and a p-type region for peripheral voltage withstanding is in contact with the trench. Feature 3 is as follows. A trench is formed in a boundary region disposed between a diode region including a p-type region and a peripheral voltage withstanding region. The p-type region of the diode and a p-type region for peripheral voltage withstanding are in contact with the trench. Feature 4 is as follows. A trench is formed in a boundary region disposed between an FET region and a diode region. A p-type body region (or a p-type region surrounding a group of trench gate electrodes) of the FET is in contact with the trench. Feature 5 is as follows. A trench is formed in a boundary region disposed between a diode region and a peripheral voltage withstanding region. A p-type region for peripheral voltage withstanding is in contact with the trench. Feature 6 is as follows. An FET is a metal-oxide-semiconductor field-effect transistor (MOSFET), a metal-insulator-semiconductor field-effect transistor (MISFET), or an insulated gate bipolar transistor (IGBT). Feature 7 is as follows. An electrode film covering an inner surface of an insulating film is thick so as to fill the trench.

### First Embodiment

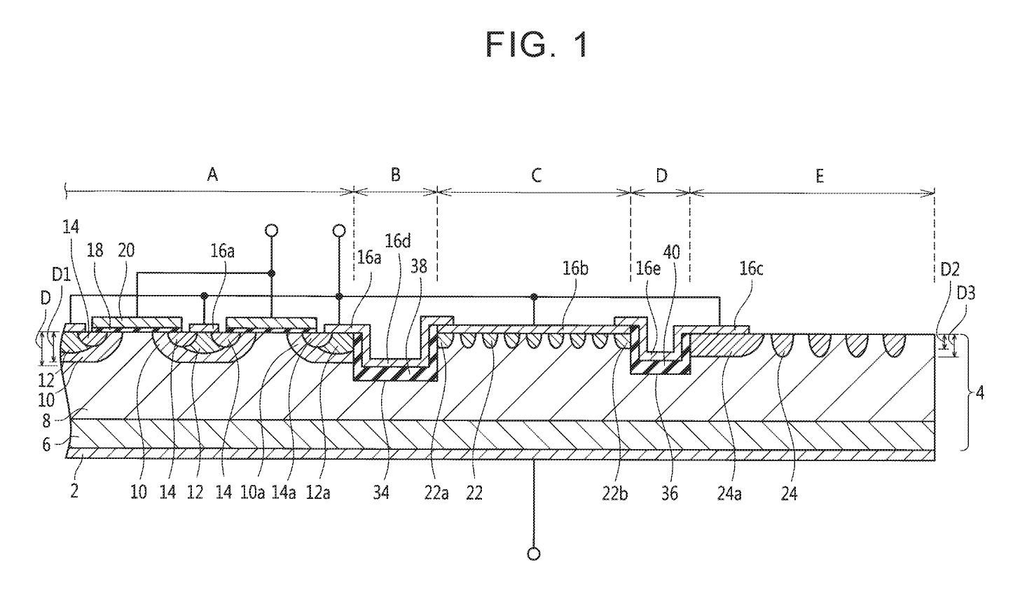

FIG. 1 illustrates a part of a section of a semiconductor device according to a first embodiment. In the figure, A indicates a field-effect transistor (FET) region, C indicates a diode region, E indicates a peripheral voltage withstanding region, B indicates a boundary region disposed between the FET region and the diode region, and D indicates a boundary region disposed between the diode region and the peripheral voltage withstanding region. An actual section extends to the left from FIG. 1, and the FET region A extends to the left in FIG. 1. In a plan view of a semiconductor substrate 4, the FET region A is formed in a central region of the semiconductor substrate 4, the diode region C is formed in an area surrounding the FET region A, and the peripheral voltage withstanding region E is formed in an area surrounding the diode region C (i.e., the peripheral voltage withstanding region E is a region positioned inward of an outer periphery of the semiconductor substrate 4 so as to extend along the outer periphery). In the whole of the section that is partially shown in FIG. 1, the regions B, C, D, E are bilaterally symmetric with respect to a center line of the region A. In the present specification, a side closer to the central region of the semiconductor substrate is called an inner side, and a side closer to a peripheral region is called an outer side.

A bottom surface electrode (a drain-cathode electrode) 2 is formed on a bottom surface of the semiconductor substrate 4. An area facing the bottom surface of the semiconductor substrate 4 is a drain-cathode layer 6 including n-type impurities at a high concentration. The drain-cathode layer 6 and the drain-cathode electrode 2 make ohmic contact with each other.

A part of the semiconductor substrate 4 other than the drain-cathode layer 6 and a body region 10 (described below) includes n-type impurities at a low concentration, and serves as an n-type drift layer 8. The semiconductor substrate 4 before processing includes n-type impurities at a concentration suitable for serving (operating) as the n-type drift layer 8.

The drain-cathode layer 6 is formed by injecting and diffusing the n-type impurities from the bottom surface of the semiconductor substrate 4 before processing. On a top side of the semiconductor substrate 4, within the FET region A, a region is formed by injecting and diffusing p-type impurities from a top surface of the semiconductor substrate 4 before processing. This region is formed in a part of an area facing the top surface of the semiconductor substrate 4, and functions as the p-type body region 10. In the semiconductor substrate 4, a region other than the drain-cathode layer 6 and the p-type body region 10 remains unprocessed and serves (operates) as the n-type drift layer 8.

The p-type body region 10 has a low p-type impurity concentration. Thus, the p-type body region 10 does not make ohmic contact with a source electrode 16a (described below) if a contact region 12 is not formed. In a part of the p-type body region 10, the part facing the top surface of the semiconductor substrate 4, the contact region 12 having a high p-type impurity concentration is formed. The contact region 12 makes ohmic contact with the source electrode 16a. A potential of the p-type body region 10 is maintained to be equal to a potential of the source electrode 16a.

A source region 14 including n-type impurities at a high concentration is formed in a part of the p-type body region 10. The source region 14 is formed in an area facing the top surface of the semiconductor substrate 4, and makes ohmic contact with the source electrode 16a. The p-type body region 10, the contact region 12, and the source region 14 extend in a vertical direction with respect to the plane of paper.

The n-type source region 14 is separated from the n-type drift layer 8 by the p-type body region 10. A gate insulating film 18 is formed on a top surface of the p-type body region 10 separating the n-type source region 14 from the n-type drift layer 8, and a gate electrode 20 is formed on a top surface of the gate insulating film 18. Note that the gate electrode 20 is insulated from the source electrode 16a by an interlayer insulator (not shown). The gate electrode 20 is opposed, via the gate insulating film 18, to the p-type body region 10 that separates the n-type source region 14 from the n-type drift layer 8.

While a positive voltage is not applied to the gate electrode 20, the n-type source region 14 is insulated from the n-type drift layer 8 by the p-type body region 10, so that no current flows between the source electrode 16a and the drain-cathode electrode 2. While the positive voltage is applied to the gate electrode 20, an inversion layer is formed in the p-type body region 10 that separates the n-type source region 14 from the n-type drift layer 8, so that a part between the n-type source region 14 and the n-type drift layer 8 has a low resistance. When the semiconductor device is used, the source electrode 16a is grounded, and the drain-cathode electrode 2 is connected to a positive potential. While a positive voltage is applied to the gate electrode 20, a current flows between the source electrode 16a and the drain-cathode electrode 2. A field-effect transistor (FET) is formed between the drain-cathode electrode 2 and the source electrode 16a. The FET may be an MOS type FET or may be an MIS type FET.

On the top surface of the semiconductor substrate 4, within the diode region C, a Schottky electrode 16b is formed. The Schottky electrode 16b is made of metal that makes Schottky contact with the n-type drift layer 8. Within an area that faces the top surface of the semiconductor substrate 4, the area being within the diode region C, p-type diffusion regions 22 are formed at uniform pitches. The p-type diffusion regions 22 extend in the vertical direction with respect to the plane of paper.

When a high potential is applied to the Schottky electrode 16b, a current flows from the Schottky electrode 16b to the drain-cathode electrode 2. When a voltage in a reverse direction is applied to a Schottky diode (in a state where the Schottky electrode 16b is grounded and the drain-cathode electrode 2 is connected to the positive potential), a depletion layer extends in the n-type drift layer 8 disposed between adjacent p-type diffusion regions 22, and thus, a current flow is prevented. The p-type diffusion region 22 improves a voltage withstanding ability of the Schottky diode.

In the peripheral voltage withstanding region E, multiple p-type guard rings 24 are formed. A field plate 16c is formed in an upper part of an innermost guard ring 24a. The p-type guard ring 24 extends the depletion layer to a peripheral portion of the semiconductor substrate 4 so as to increase a withstand voltage of the semiconductor device. An interlayer insulator may be disposed between the field plate 16c and the semiconductor substrate 4. The field plate 16c, the Schottky electrode 16b, and the source electrode 16a are configured to be electrically connected to each other. Each of the field plate 16c, the Schottky electrode 16b, and the source electrode 16a can be formed of a top surface electrode formed on the top surface of the semiconductor substrate 4.

In the boundary region B disposed between the FET region A and the diode region C, a trench 34 is formed. An inner surface (a side surface and a bottom surface) of the trench 34 is covered with an insulating film 38. An inner surface (a surface facing an inner side of the trench 34) of the insulating film 38 is covered with an electrode film 16d. The electrode film 16d is configured to be electrically connected to the source electrode 16a and the Schottky electrode 16b. The insulating film 38 includes a thin side surface and a thick bottom surface. Note that even the thin side surface is thicker than the gate insulating film 18. Further, the insulating film 38 is made of a material having a relative permittivity larger than a relative permittivity of the semiconductor substrate 4 (made of GaN or SiC).

A p-type body region 10a disposed closest to the diode region C extends into the boundary region B from the FET region A. An end of the p-type body region 10a is in contact with the trench 34, the end being in the boundary region B. A bottom surface (in FIG. 1, its depth is indicated by D) of the electrode film 16d is formed at a position deeper than a bottom surface (its depth is indicated by D1 in FIG. 1) of the body region 10a, and the body region 10a is in contact with a side surface of the trench 34 (but does not reach a bottom surface of the trench 34). An area in the vicinity of the end of the p-type body region 10a is a part where an electric field concentration easily occurs, the end being within the boundary region B. In the present embodiment, the trench 34, the insulating film 38, and the electrode film 16d are formed in that part, and thus, the electric field concentration is reduced.

A p-type diffusion region 22a disposed closest to the FET region A extends into the boundary region B from the diode region C. An end of the p-type diffusion region 22a is in contact with the trench 34, the end being within the boundary region B. The bottom surface of the electrode film 16d is formed at a position deeper than a bottom surface (its depth is indicated by D2 in FIG. 1) of the p-type diffusion region 22a, and the p-type diffusion region 22a is in contact with a side surface of the trench 34 (but does not reach the bottom surface of the trench 34). A region positioned in the vicinity of the p-type diffusion region 22a and positioned within the boundary region B is a part where an electric field concentration easily occurs. In the present embodiment, the trench 34, the insulating film 38, and the electrode film 16d are formed in that part, and thus, the electric field concentration is reduced.

A trench 36 is formed in the boundary region D disposed between the diode region C and the peripheral voltage withstanding region E. An inner surface (a side surface and a bottom surface) of the trench 36 is covered with an insulating film 40. An inner surface (a surface facing an inner side of the trench 36) of the insulating film 40 is covered with an electrode film 16e. The electrode film 16e is configured to be electrically connected to the Schottky electrode 16b and the field plate 16c. The insulating film 40 includes a thin side surface and a thick bottom surface. Note that even the thin side surface is thicker than the gate insulating film 18. Further, the insulating film 40 is made of a material having a relative permittivity larger than a relative permittivity of the semiconductor substrate 4 (made of GaN or SiC).

A p-type diffusion region 22b disposed closest to the peripheral voltage withstanding region E extends into the boundary region D from the diode region C. An end of the p-type diffusion region 22b is in contact with the trench 36, the end being within the boundary region D. A bottom surface (in FIG. 1, its depth is indicated by D) of the electrode film 16e is formed at a position deeper than a bottom surface (its depth is indicated by D2 in FIG. 1) of the p-type diffusion region 22b, and the p-type diffusion region 22b is in contact with a side surface of the trench 36 (but does not reach the bottom surface of the trench 36). A region positioned in the vicinity of the p-type diffusion region 22b and positioned within the boundary region D is a part where an electric field concentration easily occurs. In the present embodiment, the trench 36, the insulating film 40, and the electrode film 16e are formed in that part, and thus, the electric field concentration is reduced.

The p-type guard ring 24a disposed closest to the diode region C extends into the boundary region D from the peripheral voltage withstanding region E. The bottom surface of the electrode film 16e is formed at a position deeper than a bottom surface (its depth is indicated by D3 in FIG. 1) of the p-type guard ring 24a, and the p-type guard ring 24a is in contact with a side surface of the trench 36 (but does not reach the bottom surface of the trench 36). A region positioned in the vicinity of the p-type guard ring 24a and positioned within the boundary region D is a part where an electric field concentration easily occurs. In the present embodiment, the trench 36, the insulating film 40, and the electrode film 16e are formed in that part, and thus, the electric field concentration is reduced.

A left end of the boundary region B is not necessarily determined uniquely. An inversion layer is formed on the left side of a left end of a rightmost source region 14a, and thus, an area on the left side of the left end of the rightmost source region 14a is the FET region. An inversion layer is not formed on the right side of a right end of a rightmost contact region 12a, and thus, an area on the right side of the right end of the rightmost contact region 12a is not the FET region. Thus, the left end of the boundary region B is disposed at any position between the left end of the rightmost source region 14a and the right end of the rightmost contact region 12a. In FIG. 1, the right end of the rightmost contact region 12a is the left end of the boundary region B. The left end of the boundary region B illustrated in FIG. 1 is disposed between the left end of the rightmost source region 14a and the right end of the rightmost contact region 12a. No matter how the end of the boundary region B is defined, the rightmost p-type body region 10a extends into the boundary region B from the FET region A, and is in contact with the trench 34.

A right end of the boundary region B is disposed at any position between a left end of the leftmost p-type diffusion region 22a and a right end thereof. In FIG. 1, the left end of the leftmost p-type diffusion region 22a is the right end of the boundary region B. The right end of the boundary region B illustrated in FIG. 1 is disposed between the left end of the leftmost p-type diffusion region 22a and the right end thereof. No matter how the right end of the boundary region B is defined, the leftmost p-type diffusion region 22a extends into the boundary region B from the diode region C, and is in contact with the trench 34.

An electric field concentration easily occurs in a region on the right side of the rightmost p-type body region 10a and a region on the left side of the leftmost p-type diffusion region 22a. In the present embodiment, the trench 34, the insulating film 38, and the electrode film 16d are formed at the position where the electric field concentration easily occurs, and thus, the electric field concentration is reduced. Particularly, the electrode film 16d extends to a position deeper than the p-type body region 10a and the p-type diffusion region 22a, and thus, the electric field concentration is reduced effectively.

A left end of the boundary region D is disposed at any position between a left end of the rightmost p-type diffusion region 22b and a right end thereof. In FIG. 1, the right end of the rightmost p-type diffusion region 22b is the left end of the boundary region D. The left end of the boundary region D illustrated in FIG. 1 is disposed between the left end of the rightmost p-type diffusion region 22b and the right end thereof. No matter how the left end of the boundary region D is defined, the rightmost p-type diffusion region 22b extends into the boundary region D from the diode region C, and is in contact with the trench 36.

A right end of the boundary region D is disposed at any position between a left end of the leftmost p-type guard ring 24a and a right end thereof. In FIG. 1, the left end of the leftmost p-type guard ring 24a is the right end of the boundary region D. The right end of the boundary region D illustrated in FIG. 1 is disposed between the left end of the leftmost p-type guard ring 24a and the right end thereof. No matter how the right end of the boundary region D is defined, the leftmost p-type guard ring 24a extends into the boundary region D from the peripheral voltage withstanding region E, and is in contact with the trench 36.

An electric field concentration easily occurs in a region on the right side of the rightmost p-type diffusion region 22b and a region on the left side of the leftmost p-type guard ring 24a. In the present embodiment, the trench 36, the insulating film 40, and the electrode film 16e are formed at the position where the electric field concentration easily occurs, and thus, the electric field concentration is reduced. Particularly, the electrode film 16e extends to a position deeper than the p-type diffusion region 22a and the p-type guard ring 24a, and thus, the electric field concentration is reduced effectively.

In the present embodiment, the diode region C exists between the FET region A and the peripheral voltage withstanding region E. The technique described in the present specification is also effective for a case where the FET region A and the peripheral voltage withstanding region E are adjacent to each other. When a trench, an insulating film, and an electrode film are formed in a boundary region disposed between the FET region and the peripheral voltage withstanding region, an electric field concentration is reduced. When an electric field concentration occurs, a withstand voltage of a semiconductor device decreases, and thus, a current concentrates at the time of avalanche breakdown. This may cause thermal destruction in the semiconductor device. The technique described herein can deal with the problem.

In order to reduce the electric field concentration, the bottom surfaces of the insulating films 38, 40 may be made thicker than side surfaces thereof. Note that, even if the side surfaces are thin, they are thicker than the gate insulating film 18. Further, the insulating films 38, 40 may be made of a material having a relative permittivity larger than a relative permittivity of SiC or GaN constituting the semiconductor substrate 4. Further, a relationship in which the bottom surfaces of the electrode films 16d, 16e are deeper than the bottom surfaces of p-type regions such as the p-type body region 10, the p-type diffusion region 22, and the p-type guard ring 24 is also effective for reducing the electric field concentration. That is, D (the depth of the bottom surfaces of the electrode films 16d, 16e) in FIG. 1 is larger than D1 (the depth of the p-type body region 10), D2 (the depth of the p-type diffusion region 22), and D3 (the depth of the p-type guard ring 24).

The technique described herein is not limited by the manner in which the boundary regions B and D are defined. A boundary region may be defined based on a semiconductor structure inside the semiconductor substrate, a boundary region may be defined based on a distribution of an electric field, or each of the boundary regions B and D may be defined based on a magnitude of a potential change at the time when the semiconductor device operates. When the trenches 34 and 36 are formed in the boundary regions, a withstand voltage is improved.

### Second Embodiment

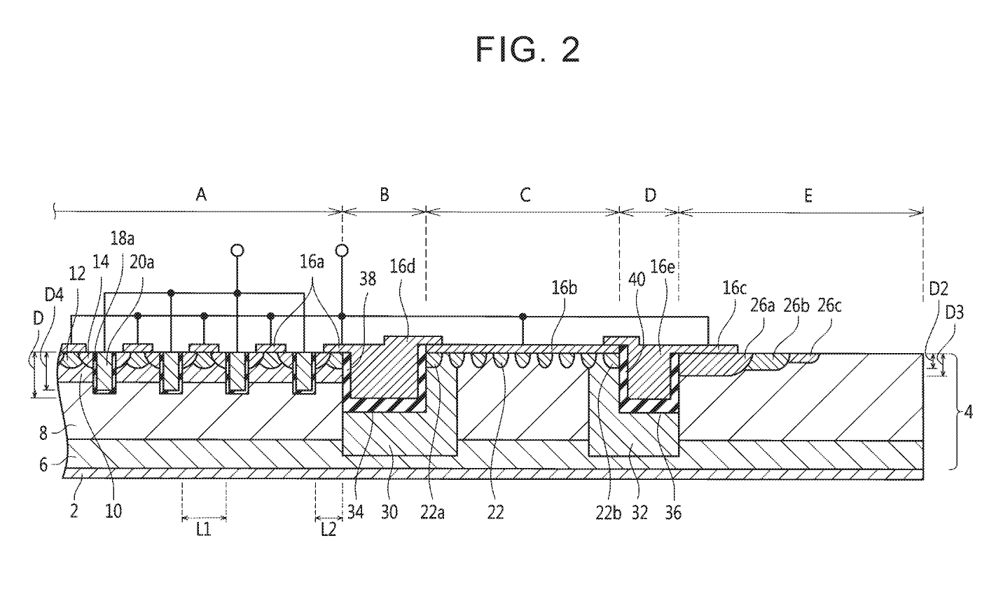

A second embodiment will be described with reference to FIG. 2. The same reference numerals are assigned to the same or corresponding members or parts as those in the first embodiment and redundant description thereof is omitted. The following describes only differences from the first embodiment.

Different Point 1 is as follows. As illustrated in FIG. 2, in the second embodiment, an n-type impurity low concentration region 30 is formed in the boundary region B, and an n-type impurity low concentration region 32 is formed in the boundary region D. The n-type impurity low concentration regions 30, 32 have a concentration further lower than that of an n-type drift layer 8, and an electric field concentration can hardly occur in the n-type impurity low concentration regions 30, 32. The n-type impurity low concentration regions 30, 32 extend through the drift layer 8 from the surface of the semiconductor substrate 4 and reach the drain-cathode layer 6. When the n-type impurity low concentration regions 30, 32 are deep enough to reach the drain-cathode layer 6, an ability to reduce an electric field concentration is improved. In the present embodiment, the n-type drift layer 8 is made of SiC or a nitride semiconductor having a band gap wider than that of silicon. Accordingly, the n-type drift layer 8 is shallow, that is, the n-type drift layer 8 has a small thickness (approximately 10 μm in the embodiment) as compared to the case of silicon, and thus, the n-type impurity low concentration regions 30, 32 extending through the drift layer 8 can be easily produced. The technique in which the n-type impurity low concentration regions 30, 32 extending through the drift layer 8 are provided is particularly useful for a case where the technique is applied to a wide gap semiconductor (with a band gap of approximately 2.2 eV or more, as exemplified by a III-V group semiconductor (e.g., a nitride semiconductor), silicon carbide, and diamond). Different Point 2 is as follows. The trench 34 is formed in the n-type impurity low concentration region 30, and the trench 36 is formed in the n-type impurity low concentration region 32. A side surface of the trench 34 on the FET region A side is disposed at substantially the same position as a side surface of the n-type impurity low concentration region 30 on the FET region A side. In contrast, a side surface of the n-type impurity low concentration region 30 on the diode region C side is disposed in an inside of the diode region C as compared to a side surface of the trench 34 on the diode region C side. The p-type diffusion region 22a closest to the FET is formed in an inside of the n-type impurity low concentration region 30. A side surface of the trench 36 on the peripheral voltage withstanding region E side is disposed at substantially the same position as a side surface of the n-type impurity low concentration region 32 on the peripheral voltage withstanding region E side. In contrast, a side surface of the n-type impurity low concentration region 32 on the diode region C side is disposed in an inside of the diode region C as compared to a side surface of the trench 36 on the diode region C side. The p-type diffusion region 22b closest to the peripheral voltage withstanding region E is formed in an inside of the n-type impurity low concentration region 32. Different Point 3 is as follows. The electrode film 16d covers the inner surface of the insulating film 38, and an inside of the trench 34 is filled with the electrode film 16d. Similarly, the electrode film 16e covers the inner surface of the insulating film 40, and an inside of the trench 36 is filled with the electrode film 16e. Different Point 4 is as follows. The FET of the first embodiment is a planar gate. The FET of the second embodiment is a trench-gate-type transistor. In FIG. 2, a reference numeral 20a indicates a trench gate electrode, and a reference numeral 18a indicates a trench-gate insulating film covering an inner surface of the trench so as to insulate the trench gate electrode 20a from the semiconductor substrate 4. Different Point 5 is as follows. In the peripheral voltage withstanding region, a reduced surface field (RESURF) structure is formed instead of the guard rings. The RESURF structure is constituted by a plurality of p-type regions 26a, 26b, 26c such that a region closer to the inner side has a higher concentration and a deeper depth and a region closer to the outer side has a lower concentration and a shallower depth. An end of the inner p-type layer 26a on the boundary region side is in contact with the side surface of the trench 36. Different Point 6 is as follows. A left end of the Schottky electrode 16b is disposed within a formation area in which the n-type impurity low concentration region 30 is formed, and a right end of the Schottky electrode 16b is disposed within a formation range of the n-type impurity low concentration region 32. Different Point 6 deals with a problem that an electric field concentration easily occurs in the vicinity of the end of the Schottky electrode 16b. Different Point 7 is as follows. The bottom surface of the electrode film 16d is deeper than a bottom surface of the trench gate electrode. Further, a bottom surface of the electrode film 16e is deeper than a bottom surface of the deepest RESURF layer 26a. That is, D (the depth of the bottom surfaces of the electrode films 16d, 16e) in FIG. 1 is larger than D4 (the depth of the trench gate electrode 20a), D2 (the depth of the p-type diffusion region 22), and D3 (the depth of the deepest p-type RESURF layer 26a). Note that, in a case of L1>L2, D may be equal to D4. In a case of D>D4, there is no restriction on L. L1 indicates an interval between the trench gate electrodes, and L2 indicates an interval between the trench 34 and the trench gate electrode 20a closest to the trench 34.

In the second embodiment, the diode region also exists between the transistor region and the peripheral voltage withstanding region. The technique described in the present specification is also effective for a case where the transistor region and the peripheral voltage withstanding region are adjacent to each other. When an n-type impurity low concentration region and a trench are formed in a boundary region, a p-type region extending to the boundary region from the transistor region is in contact with the trench, and a p-type region extending to the boundary region from the peripheral voltage withstanding region is in contact with the trench, an electric field concentration is reduced.

### Third Embodiment

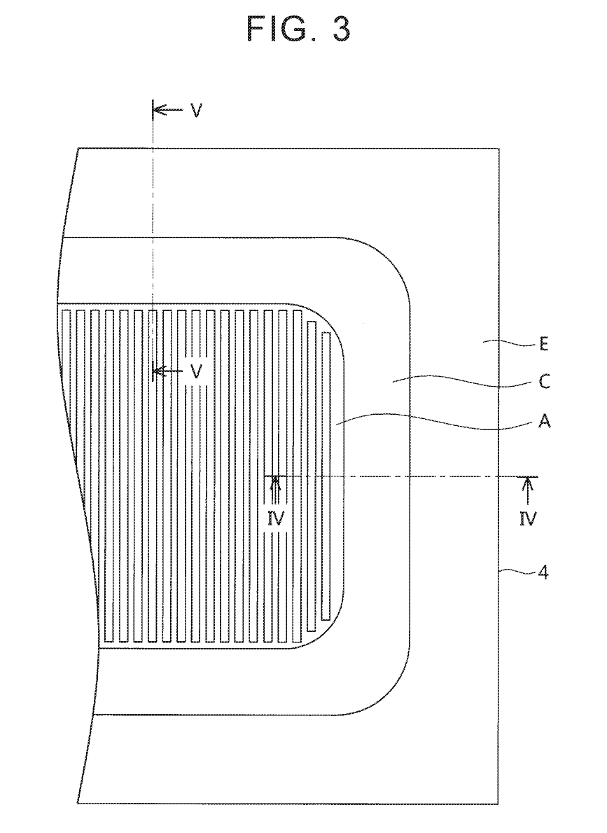

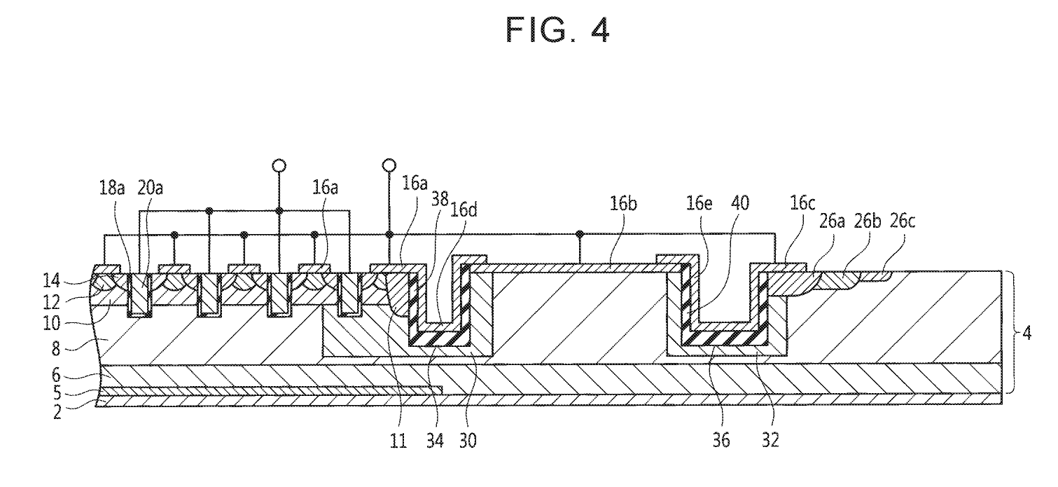

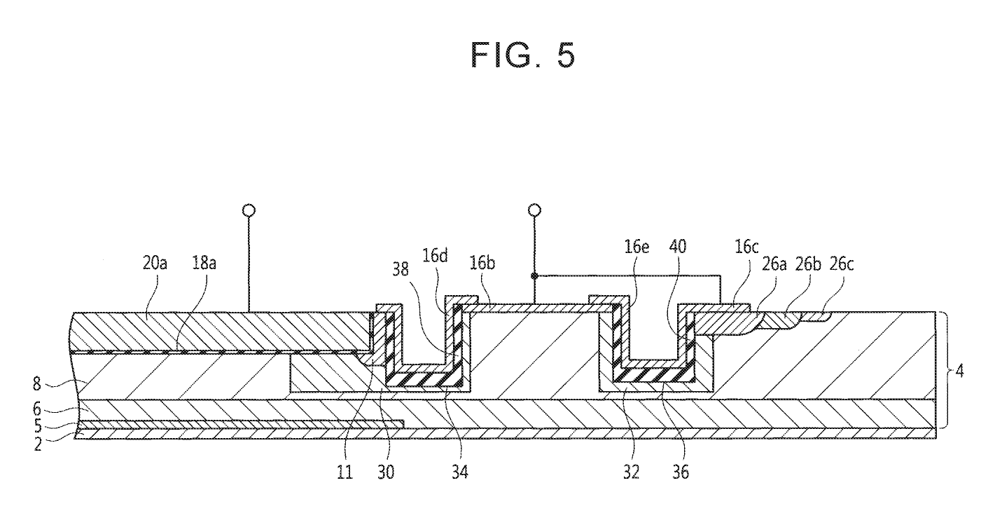

A third embodiment will be described with reference to FIGS. 3 to 5. FIG. 4 is a sectional view taken along a line IV-IV in FIG. 3 and FIG. 5 is a sectional view taken along a line V-V in FIG. 3. The same reference numerals are assigned to the same or corresponding members or parts as those in the first and second embodiments, and redundant description thereof is omitted. The following describes only differences from the first and second embodiments. Different Point 1 is as follows. The FET of each of the first and second embodiments is a monopolar transistor. An FET of the third embodiment is a bipolar transistor and is a so-called insulated gate bipolar transistor (IGBT). In some cases, the monopolar transistor is called the FET and distinguished from the bipolar IGBT. However, in the present specification, transistors that perform switching with the use of an insulated gate are collectively called the FETs. In accordance with this definition, the IGBT is also a kind of the FET. In an FET region of the third embodiment, a collector region 5 that includes p-type impurities at a high concentration is additionally provided at a position that is contact with a bottom surface electrode 2. Due to a difference between a monopolar transistor and a bipolar transistor, the bottom surface electrode 2 in the third embodiment is a collector-cathode electrode, the n-type region 14 is an emitter region, and a top surface electrode 16a is an emitter electrode. An n-type impurity high concentration layer 6 serves as both of a buffer region and a cathode layer. In a case where the FET is a bipolar transistor, a source electrode according to the disclosure indicates an emitter electrode corresponding to a source electrode of a monopolar transistor. Different Point 2 is as follows. As illustrated in FIGS. 4, 5, a p-type region 11 is formed along an outer periphery of the body region 10. The p-type region 11 is deeper than the body region 10 (i.e., the p-type region 11 has a thickness larger than that of the body region 10), and covers a longitudinal end of the trench gate electrode 20a, as illustrated in FIG. 5. In a plan view of the semiconductor substrate, the p-type region 11 surrounds a formation area of a group of the trench gate electrodes 20a (i.e., a formation area where the group of the trench gate electrodes 20a is formed). The p-type region 11 is in contact with a side surface of the trench 34, so as to deal with an electric field concentration that easily occurs in the vicinity of the p-type region 11. The depth of the bottom surface of the electrode film 16d is deeper than the bottom surface of the p-type region 11, and is also deeper than the bottom surface of the trench gate electrode 20a. Different Point 3 is as follows. Among the trench gate electrodes 20a, a trench gate electrode adjacent to the boundary region has a bottom surface positioned in an inside of the n-type impurity low concentration region 30. This prevents the occurrence of an electric field concentration in the vicinity of the bottom surface of the trench gate electrode adjacent to the boundary region, where the electric field concentration easily occurs. Different Point 4 is as follows. The diode in the third embodiment does not include a p-type diffusion region (22 in FIG. 1) that improves a withstand voltage. Accordingly, there is no restriction on a relationship between a p-type region in the diode region and the trench 34 or a relationship between the p-type region in the diode region and the trench 36. When the p-type body region 10 in the transistor region is in contact with the trench 34, it is possible to deal with the problem that an electric field concentration easily occurs in the vicinity of the p-type body region 10. When the trench 36 is in contact with the p-type guard ring 24a or the RESURF layer 26a in the peripheral voltage withstanding region on the boundary region side, it is possible to deal with the problem that an electric field concentration easily occurs in the vicinity of the p-type guard ring 24a or the RESURF layer 26a.

The specific examples of the disclosure have been described in detail. However, the examples are for illustration only, and do not limit the scope of the disclosure. Various modifications and changes may be made to the foregoing examples without departing from the scope of the disclosure. Each of the technical elements described in this specification and drawings, and various combinations thereof achieve technical utility, and the scope of the disclosure is not limited to the combinations described in the specification and drawings at the time of filing. The technique described in the specification and the drawings is able to achieve a plurality of objects at the same time, and has technical utility by achieving one of the objects.

What is claimed is:

1. A semiconductor device comprising:
a semiconductor substrate configured such that a trench is provided on a surface of the semiconductor substrate at a position of at least one of a boundary region disposed between a field-effect transistor region and a diode region, a boundary region disposed between the diode region and a peripheral voltage withstanding region, and a boundary region disposed between the field-effect transistor region and the peripheral voltage withstanding region;
an insulating film covering an inner surface of the trench; and
an electrode film covering an inner surface of the insulating film, the electrode film being configured to be electrically connected to one of a source electrode and an anode electrode.

2. The semiconductor device according to claim 1, wherein:
a p-type region is provided in an adjacent region adjacent to the boundary region; and
a bottom surface of the electrode film is disposed at a position deeper than a bottom surface of the p-type region.

3. The semiconductor device according to claim 2, wherein the p-type region provided in the adjacent region reaches a side surface of the trench.

4. The semiconductor device according to claim 1, wherein:
a trench gate electrode is provided in an adjacent region adjacent to the boundary region; and
a bottom surface of the electrode film is disposed at a position deeper than a bottom surface of the trench gate electrode.

5. The semiconductor device according to claim 1, wherein:
an n-type impurity low concentration region having an impurity concentration lower than that of an n-type drift layer is provided in the boundary region; and
the trench is provided in the n-type impurity low concentration region.

6. The semiconductor device according to claim 1, wherein the insulating film is thicker than a gate insulating film.

7. The semiconductor device according to claim 6, wherein the insulating film covering a bottom surface of the trench is thicker than the insulating film covering a side surface of the trench.

8. The semiconductor device according to claim 1, wherein a relative permittivity of the insulating film is higher than a relative permittivity of the semiconductor substrate.
